(19) United States
(12) Patent Application Publication
(10) Pub. No.: US 2025/0391674 A1
(43) Pub. Date: Dec. 25, 2025

(54) STANDBY PORT AND SUBSTRATE TREATING APPARATUS INCLUDING THE SAME

(71) Applicant: SEMES CO., LTD., Cheonan-si (KR)

(72) Inventor: Sung Pil KIM, Hwaseong-si (KR)

(73) Assignee: SEMES CO., LTD., Cheonan-si (KR)

(21) Appl. No.: 19/242,369

(22) Filed: Jun. 18, 2025

(30) Foreign Application Priority Data
Jun. 25, 2024 (KR) 10-2024-0082999

(51) Int. Cl. H01L 21/67; B08B 3/02

(52) U.S. Cl. CPC H01L 21/67051; B08B 3/02; B08B 2203/02

(57) ABSTRACT

Disclosed is an apparatus for treating a substrate, the apparatus including: a standby port located on one side of a cup unit; and a nozzle unit for supplying a treatment liquid to a substrate supported by a support unit. The standby port includes: a body having an interior space; a discharge pipe connected to the body and discharging the treatment liquid from the interior space; and a guide member located in the interior space and guiding the treatment liquid discharged from the nozzle in a direction toward the discharge pipe. The guide member includes: an upper guide; and a lower guide extending downwardly from the upper guide, and, when viewed from above, an area of the upper guide is provided larger than an area of the lower guide.

### CROSS-REFERENCE TO RELATED APPLICATIONS

This application claims priority to and the benefit of Korean Patent Application No. 10-2024-0082999 filed in the Korean Intellectual Property Office on Jun. 25, 2024, the entire contents of which are incorporated herein by reference.

### TECHNICAL FIELD

The present invention relates to an apparatus for treating a substrate, and more specifically, to a standby port in which a nozzle discharging a treatment liquid to a substrate waits, and a substrate treating apparatus including the same.

### BACKGROUND ART

To manufacture semiconductor devices or liquid crystal displays, various processes, such as photography, etching, ashing, ion implantation, thin film deposition, and cleaning, are performed on substrates. Among them, the cleaning process is a process of removing particles on the substrate by supplying a treatment liquid, such as chemical, organic solvent, or water, onto the substrate. A typical device performing a cleaning process includes a spin chuck supporting a substrate in a treatment space provided in a cup and a nozzle supplying a treatment liquid onto the substrate. The nozzle waits at a standby port located on one side of the cup when substrate cleaning is not performed. When the nozzle waits for a long time in the standby port, auto-dispense and pre-dispense are performed. Auto-dispense is to discharge a treatment liquid into the standby port at regular time intervals while the nozzle waits in the standby port. The auto-dispense may prevent the treatment liquid from hardening within pipes or nozzles. The pre-dispense is to discharge a treatment liquid from the nozzle into the standby port immediately before performing the process of treating the substrate. When starting the substrate treatment by the pre-dispense, the treatment liquid may be supplied onto the substrate at a set flow rate.

However, when a treatment liquid, such as chemical, is discharged from the nozzle to the standby port, a large amount of treatment liquid may be scattered. When a nozzle tip is positioned low, the treatment liquid discharged to the standby port is bounced back and contaminates the nozzle tip. In addition, when the nozzle tip is positioned high, the amount of fumes scattered from the discharged treatment liquid increases, and the fumes of these treatment liquids contaminate the nozzle tip.

Fume of the treatment liquid or the treatment liquid attached to the nozzle tip may contaminate the inside of the device while the nozzle is moving from the standby port to the cup, or contaminate the substrate when treating the substrate by using the nozzle.

### SUMMARY OF THE INVENTION

The present invention has been made in an effort to provide a substrate treating apparatus that improves substrate treatment efficiency during a substrate treatment process.

The present invention has also been made in an effort to provide a standby port capable of preventing a nozzle tip from being stained with a treatment liquid when the treatment liquid is discharged from a nozzle in the standby port, and a substrate treating apparatus including the same.

The objectives of the present disclosure are not limited thereto and other objectives not stated herein may be clearly understood by those skilled in the art from the following description.

An exemplary embodiment of the present invention, an apparatus for treating a substrate, the apparatus comprising: a cup unit having a treatment space for liquid-treating a substrate with a treatment liquid; a support unit for supporting a substrate within the treatment space; a standby port located on one side of the cup unit; and a nozzle unit for supplying a treatment liquid to a substrate supported by the support unit, wherein the nozzle unit includes: a nozzle for discharging the treatment liquid; and a nozzle driver for moving the nozzle between a treatment position where the nozzle supplies the treatment liquid to the substrate supported by the support unit and a standby position where the nozzle waits at the standby port, the standby port includes: a body having an interior space; a discharge pipe connected to the body and discharging the treatment liquid from the interior space; and a guide member located in the interior space and guiding the treatment liquid discharged from the nozzle in a direction toward the discharge pipe, the guide member includes: an upper guide; and a lower guide extending downwardly from the upper guide, and when viewed from above, an area of the upper guide may be provided larger than an area of the lower guide.

According to the exemplary embodiment of the present invention, the upper guide may has a rounded top surface.

According to the exemplary embodiment of the present invention, the upper guide may has a shape in which an upper surface thereof is convex upwardly.

According to the exemplary embodiment of the present invention, the upper guide has an elliptical longitudinal cross-section, and a length of the upper guide in an up and down direction may be greater than a length of the upper guide in a left and right direction.

According to the exemplary embodiment of the present invention, the lower guide may has a constant cross-sectional area in a longitudinal direction thereof.

According to the exemplary embodiment of the present invention, the standby port further includes a support plate supporting the guide member, a lower end of the guide member is coupled to the support plate, and through-holes penetrating in a vertical direction may be formed in the support plate.

According to the exemplary embodiment of the present invention, the support plate may be located at a lower end of the body or adjacent to the lower end of the body.

According to the exemplary embodiment of the present invention, the guide member is coupled to a center of the support plate, and when viewed from above, the through-holes may be arranged to surround the lower guide.

According to the exemplary embodiment of the present invention, the body includes: an upper body; and a lower body positioned below the upper body, a cross-sectional area of the upper body is provided larger than a cross-sectional area of the lower body, the upper guide is disposed within the upper body, and the support plate may be installed on the lower body.

An exemplary embodiment of the present invention, a standby port comprising: a body having an interior space; a discharge pipe connected to the body and discharging a treatment liquid from the interior space; and a guide member located in the interior space to guide the treatment liquid discharged from the nozzle in a downward direction, wherein the guide member includes: an upper guide; and a lower guide extending downwardly from the upper guide, and when viewed from above, an area of the upper guide may be provided larger than an area of the lower guide.

According to the exemplary embodiment of the present invention, the upper guide may has a rounded top surface.

According to the exemplary embodiment of the present invention, the upper guide has an elliptical longitudinal cross-section, and a length of the upper guide in an up and down direction may be greater than a length of the upper guide in a left and right direction.

According to the exemplary embodiment of the present invention, the lower guide may has a constant cross-sectional area in a longitudinal direction thereof.

According to the exemplary embodiment of the present invention, the apparatus may further include a support plate for supporting the guide member, wherein a lower end of the guide member is coupled to the support plate, and through-holes penetrating in a vertical direction may be formed in the support plate.

According to the exemplary embodiment of the present invention, the support plate may be located at a lower end of the body.

According to the exemplary embodiment of the present invention, the guide member is coupled to a center of the support plate, and when viewed from above, the through-holes may be arranged to surround the lower guide.

According to the exemplary embodiment of the present invention, the body includes: an upper body; and a lower body positioned below the upper body, a cross-sectional area of the upper body is provided larger than a cross-sectional area of the lower body, the upper guide is disposed within the upper body, and the support plate may be installed on the lower body.

An exemplary embodiment of the present invention, an apparatus for treating a substrate, the apparatus comprising: a cup unit having a treatment space for liquid-treating a substrate with a treatment liquid; a support unit for supporting the substrate within the treatment space; a standby port located on one side of the cup unit; and a nozzle unit for supplying the treatment liquid, wherein the nozzle unit includes: a nozzle for discharging the treatment liquid; and a nozzle driver for moving the nozzle between a treatment position where the nozzle supplies the treatment liquid to the substrate supported by the support unit and a standby position where the nozzle waits at the standby port, the standby port includes: a body having an interior space; a discharge pipe connected to the body and discharging the treatment liquid from the interior space; and a guide member located in the interior space and guiding the treatment liquid discharged from the nozzle in a downward direction; and a support plate for supporting the guide member, the body has an upper body and a lower body positioned below the upper body, the guide member includes: an upper guide located within the upper body; and a lower guide that extends in a downward direction from the upper guide and has a lower end located within the lower body, when viewed from above, an area of the upper guide is provided larger than an area of the lower guide, the upper guide has a shape in which an upper surface is convex upwardly, the lower guide has a constant cross-sectional area in a longitudinal direction thereof, and through-holes penetrating in a vertical direction may be formed in the support plate.

According to the exemplary embodiment of the present invention, the support plate may be located at a lower end of the lower body.

According to the exemplary embodiment of the present invention, the upper guide has an elliptical longitudinal cross-section, and a length of the upper guide in an up and down direction may be greater than a length of the upper guide in a left and right direction.

According to the exemplary embodiment of the present invention, when the treatment liquid is discharged from the nozzle at the standby port, it is possible to prevent the nozzle tip from being stained with the treatment liquid.

Effects of the present disclosure are not limited to those described above and effects not stated above will be clearly understood to those skilled in the art from the specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a top plan view schematically illustrating a substrate treating apparatus according to an exemplary embodiment of the present invention.

FIG. 2 is a diagram schematically illustrating an exemplary embodiment of the liquid treating chamber of FIG. 1.

FIG. 3 is a perspective view schematically illustrating a standby port of FIG. 2 according to an exemplary embodiment.

FIG. 4 is a longitudinal sectional view of the standby port of FIG. 3 taken along line A-A′.

FIG. 5 is a top plan view illustrating a support plate of FIG. 3 according to an exemplary embodiment.

FIG. 6 is a diagram illustrating a flow state of a treatment liquid in the standby port of FIG. 4.

FIGS. 7 and 8 are diagrams illustrating a standby port in which an upper guide is provided according to other exemplary embodiments of the present invention.

FIG. 9 is a top plan view illustrating the support plate of FIG. 3 according to another exemplary embodiment.

FIGS. 10 and 11 are perspective views schematically illustrating a standby port in which a guide member is installed according to another exemplary embodiment of the present invention.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

An expression, “and/or” includes each of the mentioned items and all of the combinations including one or more of the items. Further, in the present specification, “connected” means not only when member A and member B are directly connected, but also when member A and member B are indirectly connected by interposing member C between member A and member B.

Embodiments of the present disclosure may be modified in various ways and the scope of the present disclosure should not be construed as being limited to the embodiments to be described below. Embodiments are provided to more completely explain the present disclosure to those skilled in the art. Accordingly, the shapes of the components shown in the figures are exaggerated to enhance clearer description.

In the present invention, a substrate is described by way of example as a wafer used in the manufacture of semiconductors. Alternatively, however, the substrate may be a mask or a flat display panel.

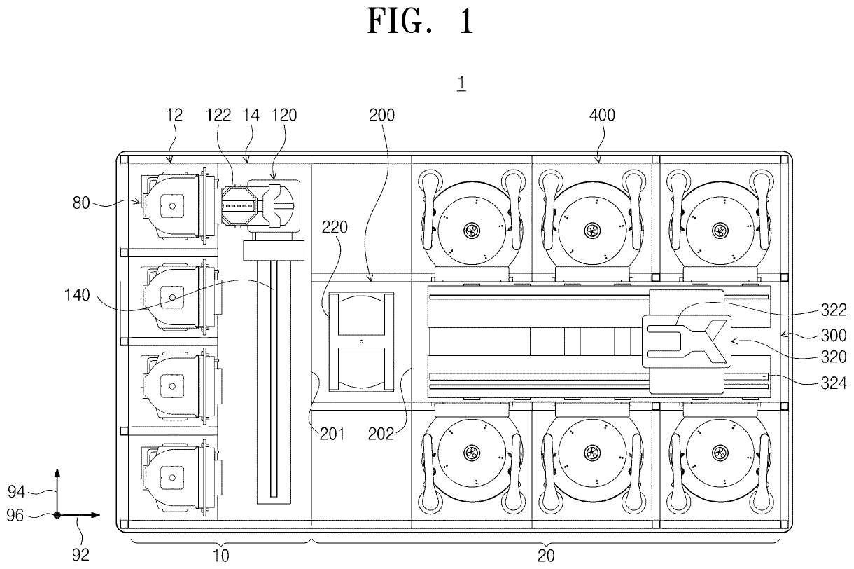

FIG. 1 is a top plan view schematically illustrating a substrate treating apparatus according to an exemplary embodiment of the present invention.

Referring to FIG. 1, a substrate treating apparatus 1 includes an index module 10 and a treating module 20. According to the exemplary embodiment, the index module 10 and the treating module 20 are disposed in one direction. Hereinafter, the direction in which the index module 10 and the treating module 20 are disposed is referred to as a first direction 92, and when viewed from above, a direction vertical to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the treating module 20, and makes the substrate W, which has been completely treated in the treating module 20, be accommodated in the container 80. A longitudinal direction of the index module 10 is provided in the second direction 94. The index module 10 includes a load port 12 and an index frame 14. Based on the index frame 14, the load port 12 is located at a side opposite to the treating module 20. The containers 80 in which the substrates W are accommodated are placed on the load ports 12. The load port 12 may be provided in plurality, and the plurality of load ports 12 may be disposed in the second direction 94.

An index robot 120 is provided to the index frame 14. Within the index frame 14, a guide rail 140 is provided with a longitudinal direction thereof in the second direction 94, and the index robot 120 may be movably provided along the guide rail 140. The indexing robot 120 includes a hand 122 on which the substrate W is placed, and the hand 122 may be provided to be movable forward and backward, rotatable about the third direction 96, and movable along the third direction 96. The plurality of hands 122 is provided while being spaced apart from each other in the vertical direction, and is capable of independently moving forward and backward.

The treating module 20 includes a buffer unit 200, a transfer chamber 300, a liquid treating chamber 400, and a controller 2.

The buffer unit 200 provides a space in which the substrate W loaded into the treating module 20 and the substrate W unloaded from the treating module 20 stay temporarily. The liquid treating chamber 400 performs a liquid treating process of treating the substrate W with a liquid by supplying a liquid onto the substrate W. The transfer chamber 300 transfers the substrate W between the buffer unit 200 and the liquid treatment chamber 400.

The transfer chamber 300 may be provided so that a longitudinal direction is the first direction 92. The buffer unit 200 may be disposed between the index module 10 and the transfer chamber 300. A plurality of liquid treatment chambers 400 is provided and may be disposed on the side of the transfer chamber 300. The liquid treatment chamber 400 and the transfer chamber 300 may be disposed in the second direction 94. The buffer unit 200 may be located at one end of the transfer chamber 300.

According to the example, the liquid treatment chambers 400 are respectively disposed on both sides of the transfer chamber 300. At one side of the transfer chamber 300, the liquid treating devices 400 may be provided in an arrangement of A×B (each of A and B is 1 or a natural greater than 1) in the first direction 92 and the third direction 96. A plurality of liquid treating chambers 400 may be provided in a structure stacked in the third direction 96.

The transfer chamber 300 includes a transfer robot 320. A guide rail 340 whose longitudinal direction extends along the first direction 92 is provided within the transfer chamber 300, and the transfer robot 320 may be provided to be movable along the guide rail 340. The transfer robot 320 includes a hand 322 on which the substrate W is placed, and the hand may be provided to be movable forward and backward, rotatable about the third direction 96, and movable along the third direction 96. The plurality of hands 322 is provided while being spaced apart from each other in the vertical direction, and is capable of independently moving forwardly and backwardly.

The buffer unit 200 includes a plurality of buffers 220 on which the substrate W is placed. The buffers 220 may be arranged with a spaced apart from each other along the third direction 96. A front face 201 and a rear face 202 of the buffer unit 200 are opened. The front face 201 of the buffer unit is the face facing the index module 10, and the back face 202 of the buffer unit is the face facing the transfer chamber 300. The index robot 120 may access into the buffer unit 200 through the front face 201 of the buffer unit, and the transfer robot 320 may access into the buffer unit 200 through the rear face 202 of the buffer unit.

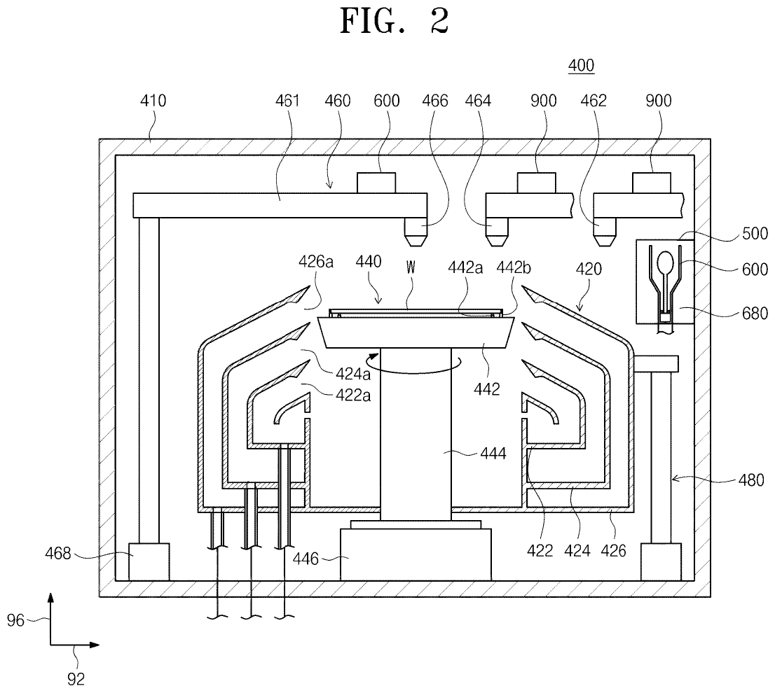

FIG. 2 is a diagram schematically illustrating an exemplary embodiment of the liquid treating chamber of FIG. 1.

Referring to FIG. 2, the liquid treating chamber 400 includes a housing 410, a cup 420, a support unit 440, a lifting unit 480, a nozzle unit 460, and a standby port 500.

The housing 410 is provided in a generally rectangular parallelepiped shape. The cup 420, the support unit 440, the nozzle unit 460, the lifting unit 480, and the standby port 500 are disposed within the housing 410.

The cup 420 has a treatment space 402 with an open top. The cup 420 includes a plurality of recovery containers 422, 424, and 426. The collection containers 422, 424, and 426 each have a collection space for collecting the liquid used to treat the substrate W. Each of the recovery containers 422, 424, and 426 is provided in a ring shape surrounding the support unit 440. During the liquid treatment process, the treatment liquid scattered by the rotation of the substrate W flows into the recovery space through the inlets 422a, 424a, and 426a of the respective recovery containers 422, 424, and 426. According to the exemplary embodiment, the cup 420 includes a first recovery container 422, a second recovery container 424, and a third recovery container 426. The first recovery container 422 is disposed to surround the support unit 440, the second recovery container 424 is disposed to surround the first recovery container 422, and the third recovery container 426 is disposed to surround the second recovery container 424. A second inlet 424a, which introduces the liquid into the second recovery container 424, may be positioned above a first inlet 422a, which introduces the liquid into the first recovery container 422, and a third inlet 426a, which introduces the liquid into the third recovery container 426, may be positioned above the second inlet 424a.

The support unit 440 supports the substrate W within the treatment space 402. The support unit 440 includes a spin chuck 442 and a drive shaft 444. The upper surface of the spin chuck 442 may be provided in a generally circular shape and may have a larger diameter than the substrate W. A chuck pin 442b is provided to an edge of the spin chuck 442. The chuck pin 442b is provided to protrude upwardly from the spin chuck 442. The chuck pin 442b supports the lateral portion of the substrate W so that the substrate W is not separated from the support unit 440 when the substrate W is rotated. Furthermore, the spin chuck 442 is provided with a support pin 442a for supporting the rear surface of the substrate W. The support pin 442a is provided such that the upper end thereof protrudes from the spin chuck 442 so that the substrate W is spaced apart from the spin chuck 442 by a predetermined distance. The support pin 442a is disposed closer to the center of the spin chuck 442 than the chuck pin 442b. The drive shaft 444 is driven by the driver 446, is connected to the center of the bottom surface of the substrate W, and rotates the spin chuck 442 with respect to the central axis thereof.

The lifting unit 480 adjusts a relative height between the cup 420 and the support unit 440. In one example, the lifting unit 480 moves the cup 420 in an upward and downward direction. By the up and down movement of the cup 420, a relative height between the cup 420 and the substrate W is changed. Through this, the recovery containers 422, 424, and 426 to which pre-treatment liquids are recovered are changed according to the type of liquid supplied to the substrate W, so that it is possible to separate and recover the liquids. Unlike the description, the cup 420 may be fixedly installed, and the lifting unit 480 may move the support unit 440 in the vertical direction.

The nozzle unit 460 supplies a liquid onto the substrate W supported on the support unit 440. liquids of multiple types are provided, and can be sequentially supplied onto the substrate W. The nozzle unit 460 includes a first nozzle 462, a second nozzle 464, a third nozzle 466, and a nozzle driver 468. The first nozzle 462 supplies a treatment liquid of a first component onto the substrate W. The treatment liquid of the first component may be a solution that removes any residual film or foreign substances remaining on the substrate W. For example, the treatment liquid of the first component may be an acid-based chemical, such as sulfuric acid, hydrofluoric acid, phosphoric acid, or hydrochloric acid, an alkaline-based chemical, such as ammonia, or a mixture of acid and alkaline-based chemicals. The second nozzle 464 supplies the treatment liquid of a second component onto the substrate W. For example, the treatment liquid of the second component may be an organic solvent. The organic solvent may be isopropyl alcohol (IPA). The third nozzle 466 supplies the treatment liquid of a third component onto the substrate W. For example, the treatment liquid of the third component may be water. The first nozzle 462, the second nozzle 464, and the third nozzle 466 are supported by different arms 461, and these arms 461 may be moved independently by the nozzle driver 468. Selectively, the first nozzle 462, the second nozzle 464, and the third nozzle 466 may be mounted on the same arm 461 and simultaneously moved by the nozzle driver 468. Hereinafter, one of the first nozzle 462, the second nozzle 464, and the third nozzle 466 will be collectively referred to as a nozzle 490.

The standby port 500 is disposed outside the cup 420 within the housing 410. A position at which the nozzle 490 supplies the treatment liquid onto the substrate W is referred to as a treatment position P, and a position at which the nozzle 490 waits after the nozzle 490 completes the supply of the treatment liquid onto the substrate W is referred to as a standby position R. When viewed from above, the nozzle 490 at the standby position R overlaps the standby port 500. The nozzle 490 may be moved between the treatment position P and the standby position R by the nozzle driver 468. Also, the nozzle 490 may be vertically moved in the third direction 96 by the nozzle driver 468. The standby position R of the nozzle 490 may be a position higher than the standby port 500. Optionally, the standby position R may be a position at which the nozzle tip 494 is inserted into an interior space 502 of the standby port 500. The nozzle 490 located at the standby position R discharges the treatment liquid remaining in the nozzle 490 onto the standby port 500.

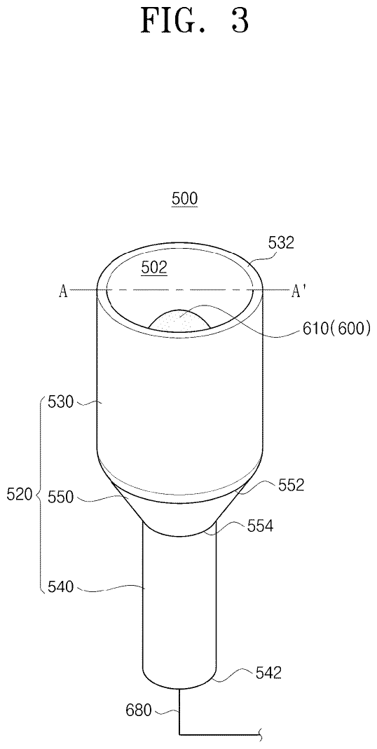

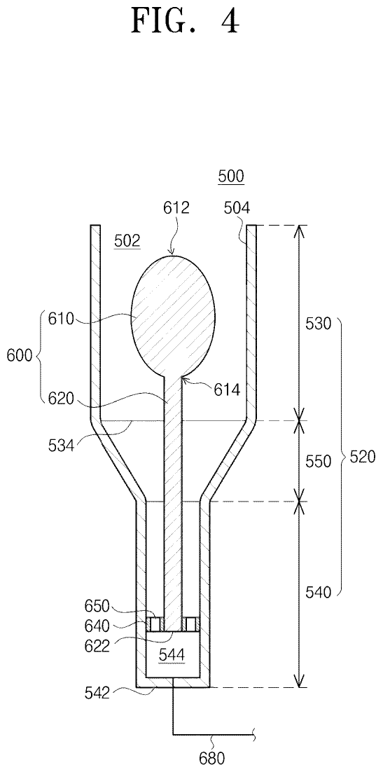

FIG. 3 is a perspective view schematically illustrating the standby port of FIG. 2 according to an exemplary embodiment. FIG. 4 is a longitudinal sectional view of the standby port of FIG. 3 taken along line A-A′.

Referring to FIGS. 3 and 4, the standby port 500 includes a body 520, a guide member 600, a support plate 640, and a discharge pipe 680.

The interior space 502 having an open upper portion is formed in the body 520. The body 520 includes an upper body 530, a lower body 540, and a connector 550. The upper body 530 may have the same cross-sectional area in the vertical direction. For example, the upper body 530 may be provided in a cylindrical shape having a space in which upper and lower portions are open. The lower body 540 is located below the upper body 530. The lower body 540 may have the same cross-sectional area in the vertical direction. For example, the lower body 540 may be provided in a cylindrical shape having a space in which an upper portion is open. The cross-sectional area of the upper body 530 is provided wider than the cross-sectional area of the lower body 540. The connector 550 connects the upper body 530 and the lower body 540 to each other. The connector 550 has a shape with cross-sectional area that decreases from the upper body 530 to the lower body 540. For example, the connector 550 may be provided in a conical shape in which an upper surface 552 has a larger area than a lower surface 554.

The discharge pipe 680 discharges the treatment liquid discharged to the interior space 502 of the body 520 to the outside. The discharge pipe 680 is coupled to the lower body 540. According to the exemplary embodiment, the discharge pipe 680 may be coupled to the bottom surface 542 of the lower body 540.

The guide member 600 guides the treatment liquid discharged from the nozzle 490 to the discharge pipe 680. The guide member 600 is located in the interior space 502 of the body 520. The guide member 600 includes an upper guide 610 and a lower guide 620.

When viewed from above, the cross-sectional area of the upper guide 610 is provided to be wider than the cross-sectional area of the lower guide 620. The upper surface 612 of the upper guide 610 is formed to be round. The upper surface 612 of the upper guide 610 may have an upwardly convex shape. According to the example, the longitudinal section of the upper guide 610 may be provided in an elliptical shape. In this case, the long axis of the upper guide 610 may be provided in the transverse direction, and the short axis of the upper guide 610 may be provided in the longitudinal direction. Accordingly, the length of the upper guide 610 in the vertical direction may be provided to be longer than the length in the left and right directions. An upper surface 612 of the upper guide 610 is positioned lower than an upper end 532 of the upper body 530. Also, a lower surface 614 of the upper guide 610 is positioned higher than a lower end 534 of the upper body 530. According to the example, the upper guide 610 may be positioned in an upper region in the interior space 502 of the upper body 530.

The lower guide 620 is provided in a bar shape. The longitudinal direction of the lower guide 620 may have a vertical longitudinal direction. The cross-section of the lower guide 620 may be provided in a circular shape. The lower guide 620 may be provided with a constant cross-sectional area in a longitudinal direction thereof. The lower guide 620 extends downwardly from the upper guide 610. A lower end 622 of the lower guide 620 is positioned in the interior space 544 of the lower body. According to the example, the lower end 622 of the lower guide 620 may be located adjacent to or on the bottom surface 542 of the lower body 540.

The guide member 600 is supported by the support plate 640.

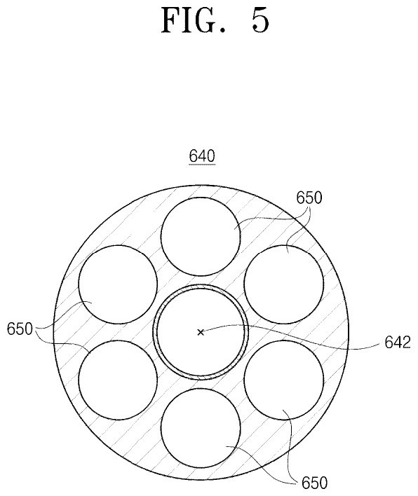

FIG. 5 is a top plan view illustrating the support plate of FIG. 3 according to the exemplary embodiment.

The support plate 640 is provided at a position adjacent to or on the bottom surface 542 of the lower body 540. Referring to FIG. 5, when viewed from above, the support plate 640 has the same shape and size as the interior space 544 of the lower body 540. For example, the support plate 640 may have a disk shape. The support plate 640 has a through-hole 650 penetrating in the vertical direction. A plurality of through-holes 650 is formed. For example, six through-holes 650 may be provided. When viewed from above, each of the through-holes 650 may be formed in a circular shape. According to the example, the through-holes 650 may be arranged to surround a center 642 of the support plate 640. The lower guide 620 may be coupled to the center 642 of the support plate 640. A groove or a hole into which the lower guide 620 is inserted may be formed at the center 642 of the support plate 640.

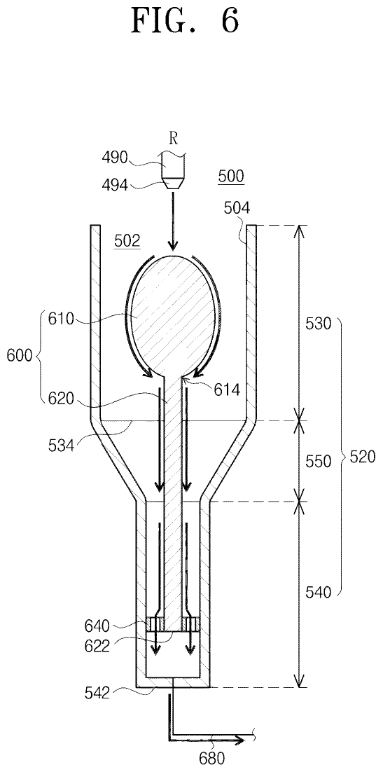

FIG. 6 is a diagram illustrating a flow state of a treatment liquid in the standby port of FIG. 4.

When the treatment liquid is discharged, the treatment liquid comes into contact with the upper surface 612 of the upper guide 610. The upper surface 612 of the upper guide 610 is provided in a rounded shape. As a result, the treatment liquid is not scattered onto the inner wall 504 or the nozzle tip 494 of the standby port 500. The treatment liquid flows downwardly along the upper guide 610, flows along the upper surface 612 of the upper guide 610, the lower surface 614 of the upper guide 610, and the lower guide 620, and is discharged to the discharge pipe 680 through the through hole 650 of the support plate 640.

The treatment of the substrate W using the substrate treating apparatus 1 and the standby port 500 according to the present invention is performed in the following operations. First, the treatment liquid is discharged from the loaded substrate W to treat the substrate W. After that, the nozzle 490 moves to the standby position R, and the substrate W is unloaded. After that, the new substrate W is loaded. The nozzle 490 moves to the treatment position P and discharges the treatment liquid to the new substrate W to treat the substrate W. This process is repeated until the treatment of the substrate W of one or a set number of lots is completed. When the treatment of the substrate W of the corresponding lot is completed, it waits until the substrate of the next lot W is loaded. While waiting, the nozzle 490 moves back to the standby position R. After that, the nozzle 490 performs auto-dispensing. Thereafter, when the substrate W of the next lot is loaded, the pre-dispensing is performed and then the substrate W moves to the treatment position P to continue the treatment of the substrate W.

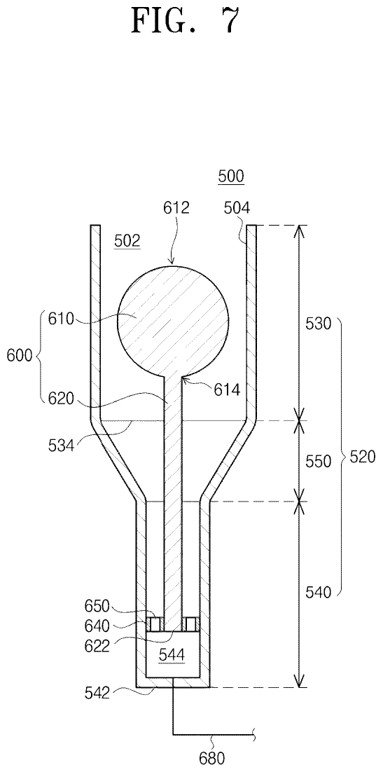

In the above exemplary embodiment, it has been described that the upper guide 610 is provided in an elliptical shape. However, the shape of the upper guide 610 is not limited thereto. As illustrated in FIG. 7, the upper guide 610 may be provided in a spherical shape.

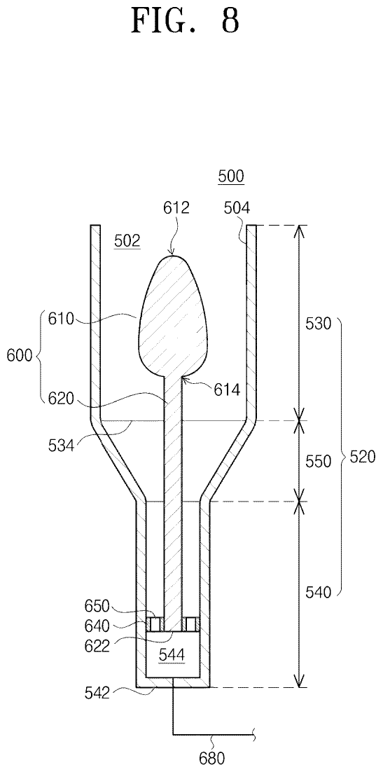

The upper guide 610 may be provided in a shape other than a sphere or an ellipse. Referring to FIG. 8, the lower surface 614 of the upper guide 610 may be provided to be rounded more smoothly than the upper surface 612 of the upper guide 610. That is, the upper guide 610 may be provided in a shape in which the upper surface 612 and the lower surface 614 are rounded and the upper surface 612 and the lower surface 614 are asymmetrical to each other. For example, the upper guide 610 may be provided with a radius of curvature of the lower surface 614 greater than a radius of curvature of the upper surface 612.

In the above exemplary embodiment, it has been described that the cross-sectional area of the lower guide 620 is constantly provided in the longitudinal direction. However, the present invention is not limited thereto, and the cross-sectional area of the lower guide 620 may be provided as non-constant.

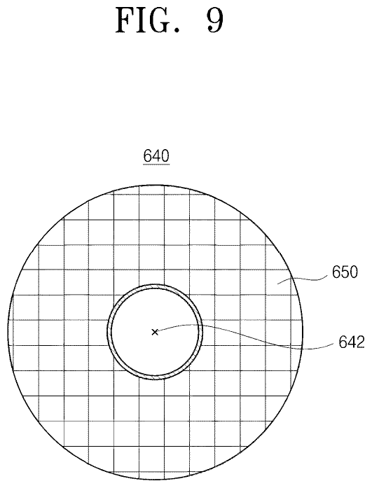

In the above-described exemplary embodiment, it has been described that the through-hole 650 is formed in the support plate 640. However, this is illustrative and the present invention is not limited thereto. As illustrated in FIG. 9, the support plate 640 may be provided as a mesh, and the guide member 600 may be coupled to the center 642 of the support plate 640.

In the above exemplary embodiment, it has been described that a groove or a hole is formed in the center 642 of the support plate 640 in the vertical direction. According to the exemplary embodiment, the guide member 600 may be screwed to the support plate 640.

Additionally, a cleaning unit for cleaning the nozzle 490 may be provided at the standby port 500.

In the above-described exemplary embodiment, the present invention has been described based on the case where one nozzle 490 waits in one standby port 500 as an example. However, the nozzle unit 460 may include a plurality of nozzles 490 driven simultaneously. In this case, a plurality of nozzles 490 may simultaneously waits at the standby port 1500.

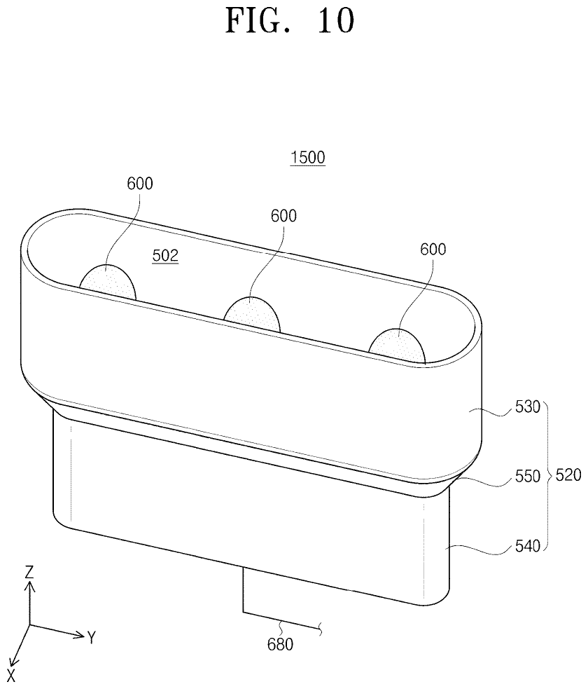

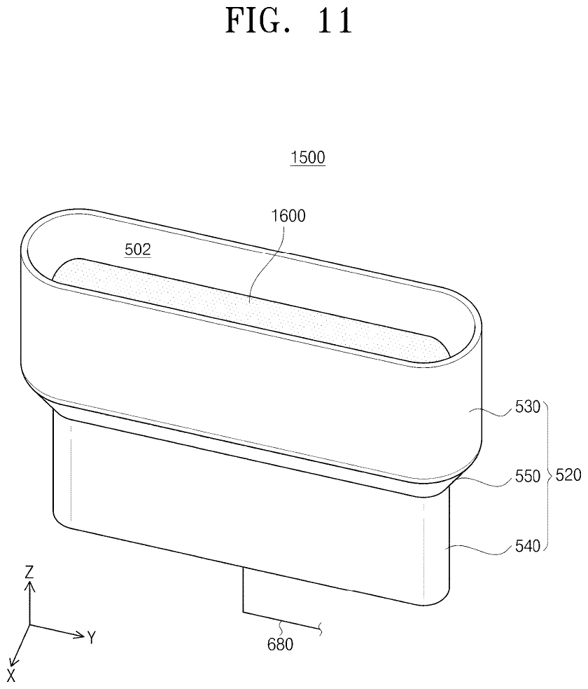

A plurality of nozzles 490 may be provided to wait at the standby port 1500. In this case, a plurality of guide members 600 may be provided at the standby port 1500. Referring to FIG. 10, a plurality of guide members 600 may be arranged in a line in the same direction as the arrangement direction of the nozzles 490. Alternatively, as illustrated in FIG. 11, one guide member 1600 may be provided at the standby port 1500, but the guide member 1600 may have a long length in the arrangement direction of the nozzles 490.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. An apparatus for treating a substrate, the apparatus comprising:
a cup unit having a treatment space for liquid-treating a substrate with a treatment liquid;
a support unit for supporting a substrate within the treatment space;
a standby port located on one side of the cup unit; and
a nozzle unit for supplying a treatment liquid to a substrate supported by the support unit,
wherein the nozzle unit includes:
a nozzle for discharging the treatment liquid; and
a nozzle driver for moving the nozzle between a treatment position where the nozzle supplies the treatment liquid to the substrate supported by the support unit and a standby position where the nozzle waits at the standby port,
the standby port includes:
a body having an interior space;
a discharge pipe connected to the body and discharging the treatment liquid from the interior space; and
a guide member located in the interior space and guiding the treatment liquid discharged from the nozzle in a direction toward the discharge pipe,
the guide member includes:
an upper guide; and
a lower guide extending downwardly from the upper guide, and
when viewed from above, an area of the upper guide is provided larger than an area of the lower guide.

2. The apparatus of claim 1, wherein the upper guide has a rounded top surface.

3. The apparatus of claim 2, wherein the upper guide has a shape in which an upper surface thereof is convex upwardly.

4. The apparatus of claim 2, wherein the upper guide has an elliptical longitudinal cross-section, and
a length of the upper guide in an up and down direction is greater than a length of the upper guide in a left and right direction.

5. The apparatus of claim 1, wherein the lower guide has a constant cross-sectional area in a longitudinal direction thereof.

6. The apparatus of claim 1, wherein the standby port further includes a support plate supporting the guide member,
a lower end of the guide member is coupled to the support plate, and
through-holes penetrating in a vertical direction are formed in the support plate.

7. The apparatus of claim 6, wherein the support plate is located at a lower end of the body or adjacent to the lower end of the body.

8. The apparatus of claim 6, wherein the guide member is coupled to a center of the support plate, and
when viewed from above, the through-holes are arranged to surround the lower guide.

9. The apparatus of claim 6, wherein
the body includes:
an upper body; and
a lower body positioned below the upper body,
a cross-sectional area of the upper body is provided larger than a cross-sectional area of the lower body,
the upper guide is disposed within the upper body, and
the support plate is installed on the lower body.

10. A standby port comprising:
a body having an interior space;
a discharge pipe connected to the body and discharging a treatment liquid from the interior space; and
a guide member located in the interior space to guide the treatment liquid discharged from the nozzle in a downward direction,
wherein the guide member includes:
an upper guide; and
a lower guide extending downwardly from the upper guide, and
when viewed from above, an area of the upper guide is provided larger than an area of the lower guide.

11. The standby port of claim 10, wherein the upper guide has a rounded top surface.

12. The standby port of claim 11, wherein the upper guide has an elliptical longitudinal cross-section, and
a length of the upper guide in an up and down direction is greater than a length of the upper guide in a left and right direction.

13. The standby port of claim 10, wherein the lower guide has a constant cross-sectional area in a longitudinal direction thereof.

14. The standby port of claim 10, further comprising:
a support plate for supporting the guide member,
wherein a lower end of the guide member is coupled to the support plate, and
through-holes penetrating in a vertical direction are formed in the support plate.

15. The standby port of claim 14, wherein the support plate is located at a lower end of the body.

16. The standby port of claim 14, wherein the guide member is coupled to a center of the support plate, and
when viewed from above, the through-holes are arranged to surround the lower guide.

17. The standby port of claim 14, wherein the body includes:
an upper body; and
a lower body positioned below the upper body,
a cross-sectional area of the upper body is provided larger than a cross-sectional area of the lower body,
the upper guide is disposed within the upper body, and
the support plate is installed on the lower body.

18. An apparatus for treating a substrate, the apparatus comprising:
a cup unit having a treatment space for liquid-treating a substrate with a treatment liquid;
a support unit for supporting the substrate within the treatment space;
a standby port located on one side of the cup unit; and
a nozzle unit for supplying the treatment liquid,
wherein the nozzle unit includes:
a nozzle for discharging the treatment liquid; and
a nozzle driver for moving the nozzle between a treatment position where the nozzle supplies the treatment liquid to the substrate supported by the support unit and a standby position where the nozzle waits at the standby port,
the standby port includes:
a body having an interior space;
a discharge pipe connected to the body and discharging the treatment liquid from the interior space; and
a guide member located in the interior space and guiding the treatment liquid discharged from the nozzle in a downward direction; and
a support plate for supporting the guide member,
the body has an upper body and a lower body positioned below the upper body,
the guide member includes:
an upper guide located within the upper body; and
a lower guide that extends in a downward direction from the upper guide and has a lower end located within the lower body,
when viewed from above, an area of the upper guide is provided larger than an area of the lower guide,
the upper guide has a shape in which an upper surface is convex upwardly,
the lower guide has a constant cross-sectional area in a longitudinal direction thereof, and
through-holes penetrating in a vertical direction are formed in the support plate.

19. The apparatus of claim 18, wherein the support plate is located at a lower end of the lower body.

20. The apparatus of claim 18, wherein the upper guide has an elliptical longitudinal cross-section, and
a length of the upper guide in an up and down direction is greater than a length of the upper guide in a left and right direction.
